(19) United States
(12) Patent Application Publication
(10) Pub. No.: US 2025/0226393 A1
(43) Pub. Date: Jul. 10, 2025

(54) Sulfide Coatings For Ultra-Stable Cathodes Of Lithium Batteries

(71) Applicant: BOARD OF TRUSTEES OF THE UNIVERSITY OF ARKANSAS, Little Rock, AR (US)

(72) Inventors: Xiangbo MENG, Fayetteville, AR (US); Xin WANG, Fayetteville, AR (US)

(73) Assignee: BOARD OF TRUSTEES OF THE UNIVERSITY OF ARKANSAS, Little Rock, AR (US)

(21) Appl. No.: 18/849,470

(22) PCT Filed: Jun. 14, 2022
(86) PCT No.: PCT/US2022/033486

§ 371 Date: Sep. 20, 2024

Related U.S. Application Data
(60) Provisional application No. 63/210,467, filed on Jun. 14, 2021.

(51) Int. Cl. H01M 4/36; H01M 4/02; H01M 4/04; H01M 4/525; H01M 4/58; H01M 10/0525; H01M 10/42

(52) U.S. Cl. CPC H01M 4/366; H01M 4/0428; H01M 4/525; H01M 4/5815; H01M 10/0525; H01M 10/4235; H01M 2004/028

(57) ABSTRACT

A lithium-ion battery including a cathode having a sulfide coating thereon; such sulfides having different chemical compounds, including Li₂S, Na₂S, K2S, Rb2S, Cs2S, Fr2S, BeS, MgS, SrS, BaS, RaS, Sc₂S₃, Y₂S₃, TiS₂, ZrS₂, HfS₂, V₂S₅, Nb₂S₅, Ta₂S₅, CrS₂, MoS₂, WS₂, MnS, MnS₂, TcS₂, ReS₂, Fe₂S₃, Ru₂S₃, Os₂S₃, CoS, CoS₂, Co₃S₄, Co₉S₈, RhS, RhS₂, NiS, NiS₂, PdS, PdS₂, PtS, PtS₂, CuS, Cu₂S, Ag₂S, AgS, Au₂S, AuS, ZnS, CdS, HgS, B₂S₃, Al₂S₃, Ga₂S₃, In₂S₃, SiS, SiS₂, GeS, GeS₂, SnS, SnS₂, PbS, PbS₂, P₂S₅, As₂S₅, Sb₂S₅, Bi₂S₅, their compounds, and a method for making the same. The cathode can be LiNiₓMn_{y}Co_{z}O₂ (NMCs, x+y +z=1), LiMn₂O₄ (LMO), olivine LiFePO₄ (LFP), LiCoO₂ (LCO), LiNi_{0.8}Co_{0.05}Al_{0.05}O₂ (NCA), layered Li-rich Mn-based cathodes with the chemical formular of xLi₂MnO₃# (1−x) LiTMO₂ (TM=Ni, Mn, Co, etc.), and a method for making the same.

### RELATED APPLICATIONS

This application is a 371 National Phase of PCT/US2022/033486 filed on 14 Jun. 2022, which claims priority to U.S. Provisional Application No. 63/210,467, filed on 14 Jun. 2021, both of which are incorporated herein in their entirety.

### STATEMENT REGARDING FEDERALLY SPONSORED RESEARCH & DEVELOPMENT

This invention was made with government support by the National Science Foundation Grant No. OIA-1457888. The government has certain rights in the invention.

### BACKGROUND OF THE INVENTION

Battery-powered electric vehicles (BEVs) promise a clean and green future while reducing dependency on traditional fossil fuels. However, the market penetration of BEVs is still slow, due to a series of challenges. Among these challenges, many are dominated by the state-of-the-art BEV batteries, i.e., lithium-ion batteries (LIBs), such as limited driving range, high cost, and long charging time. To remove these hurdles of BEVs, next-generation LIBs and beyond are undergoing intensive investigations. They are expected to meet the following requirements: a high energy density of≥300 Wh/kg for a driving range of≥300 miles, an affordable cost of≤$125 /kWh, reliable safety free of fires and explosions, and a long lifetime of ≥15 calendar years.

In pursuing these new battery technologies, cathode materials play a crucial role in the whole battery cell system, including working voltage, specific capacity, energy and power density, cycle life, and safety. Currently, the cathodes available for BEVs are spinel LiMn₂O₄ (LMO), olivine LiFePO₄ (LFP), layered LiCoO₂ (LCO), layered LiNi_{0.8}Co_{0.15}Al_{0.05}O₂ (NCA), and layered LiNiₓMn_{y}Co_{z}O₂ (NMCs, x+y+z=1). Among all these available cathode materials, LiNi_{0.8}Mn_{0.1}Co_{0.1}O₂ (NMC811) is among the most promising cathodes.

NMC811 is a promising candidate (FIG. 1) because of its high capacity, high voltage, and cost-effectiveness. With varying Ni-Mn-Co compositions, NMC oxides can be LiNi_{1/3}Mn_{1/3}Co_{1/3}O₂ (NMC111), LiNi_{0.4}Mn_{0.4}Co_{0.2}O₂ (NMC442), LiNi_{0.5}Mn_{0.3}Co_{0.2}O₂ (NMC532), LiNi_{0.6}Mn_{0.2}Co_{0.2}O₂ (NMC622), and NMC811. In these NMC cathode materials, each transition metal (TM) ion plays its particular roles. Specifically, Ni ions contribute to the majority of capacity through the Ni²⁺/Ni³⁺ and Ni³⁺/Ni⁴⁺ redox couples, Co ions suppress Ni/Li cationic mixing in the synthesis and cycling while increasing rate capability, and Mn ions stabilize the structure and enhance thermal stability. Thus, an increased Ni content enables a higher capacity and lower weight of NMCs. To date, NMCs of x≤0.6 have been commercialized, but it is particularly challenging to commercialize NMC811 or the ones with an even higher Ni content. Compared to a capacity of ˜180 mAh/g of NMC622 (charged to 4.3 V), NMC811 can enable much higher capacities from 215 mAh/g (charged to 4.2 V) to 260 mAh/g (charged to 4.7 V). Owing to the reduction in the expensive Co element, at the same time, the cost of NMC811 will be significantly decreased.

As illustrated in FIG. 1, NMC811 can enable a capacity and energy density comparable to those of commercial NCA but much higher than those of commercial LCO, LMO, and LFP. Although NCA and NMC811 exhibit some similar chemical composition, NMC811 has higher thermal stability and more uniform chemical composition. Thus, NMC811 is a promising cathode for high-energy LIBs and beyond to power BEVs. Given these advantages of NMC811 , all major EV manufacturers are planning to use NMC811 for some of their EV models, including VW, GM, Tesla, BYD, BAIC, Nissan, Hyundai, etc. It is predicted that NMC811 will occupy >60% of NMC-based EV batteries in 2025. Due to its high Ni content of 80% and high charge voltages, however, NMC811 suffers from many more challenges in performance and safety, exhibited as continuous drop in capacity and voltage accompanied by continuous increase in impedance. All these issues hinder NMC811 from commercialization.

NMC powders generally are micron-sized spherical particles (secondary particles, FIG. 2A). They are polycrystalline and consist of many nanosized single crystals (primary particles, FIG. 2B). All NMCs have similar differential capacity-voltage ((dQ/dV)-V) profiles (the trace in FIG. 2C). During the charge process, NMCs experience multiple phase transitions from hexagonal (H1) to monoclinic (M) and hexagonal (H2 and H3) phases, while these phases are reversed during the subsequent discharge process. The voltage for the H2→H3 phase transition decreases with increased Ni contents, which is ˜4.7 V (voltages are against Li/Li+) for NMCs of x≤0.6 (e.g., NMC622 and NMC532), but is ˜4.3 V for NMC811.

In applications, NMCs suffer from many issues. These issues can be nearly ascribed to two intrinsic problems: (1) oxygen release from lattices of NMCs at high potentials or higher temperatures and (2) the inevitable presences of residual lithium compounds (RLCs, mainly LiOH and Li₂CO₃) on the surface of NMCs. RLCs can cause battery gassing and electrode structural degradation while oxygen release can lead to several other serious issues, including irreversible phase transition, electrolyte decomposition and depletion, metal ion dissolution, and mechanical cracking. Compared to NMCs of x≤0.6, NMC811 faces more severe issues as discussed below.

Oxygen release occurs near the onset of H2→H3 phase transition, corresponding to a 70-80% state-of-charge (SOC). Released oxygen can oxidize electrolyte solvents and generate gases and H₂O. The onset potential depends on the Ni content, which is up to 4.4 V for NMCs of x≤0.6, but only up to 4.0 V for NMC811. Thus, oxygen release is a key cause for the depletion of electrolyte solvents, cathode degradation, and safety hazards. It is particularly challenging for NMC811.

Among the three TM ions (Ni²⁺, Co²⁺, and Mn²⁺), Ni²⁺ ions (0.69 Å) have similar ionic radius as that of Li⁺ ions (0.76 Å) and are prone to mix with Li⁺ ions partially. This Ni/Li cationic mixing reduces Li⁺ mobility and the capacity of NMCs. The mixing degree increases with the Ni content, SOC, and operational temperature.

The Ni/Li mixing and oxygen release further cause the irreversible transformation of the crystal structure from layered over spinel to NiO-like rocksalt phase. Oxygen release in the bulk NMCs is kinetically hindered, due to long oxygen diffusion paths. Thus, the irreversible layered-spinel-rocksalt phase transition is more severe in the near surface of NMC particles and of cracks than in the bulk of cathode particles. Since the NiO-like rocksalt phase and solvent decomposition products (i.e., solid electrolyte interphase, SEI) are neither electrochemically active nor ionically conductive, their accumulation results in the formation of a thick and highly resistive surface layer, which consequently increases the battery's impedance. To make the situation worse, the layered-spinel-rocksalt phase transition aggravates with increased SOC and cycling number, and eventually the characteristics for the H2→H3 phase transition disappears from FIG. 2c, resulting in the declines of capacity and voltage.

Released oxygen can react with electrolyte solvents to produce H₂O. H₂O can further react with LiPF₄ with some production of HF. Then, HF reacts with metal oxides (MOs) of NMCs to form soluble MF₂ and H₂O. Thus, this is a self-accelerating process driven by oxygen release.

Oxygen release and the irreversible phase transition generate a large strain during a charging process of NMC powders (FIG. 3A), which leads to the dramatic shrinkage of lattice unit cell volume in H2→H3 (FIG. 3B). Consequently, there are intragranular cracks developed in primary particles and intergranular cracks (FIG. 3C) in secondary particles during charge-discharge processes. Liquid electrolytes can penetrate these microcracks and react with released oxygen (FIG. 3D). These reactions can accelerate gas generation, form SEI, and increase cell impedance. Therefore, these unfavorable changes lead to declines of battery capacity and working voltage. In addition, microcracking can lead to the detachment of NMC active materials from the electrodes. This further leads to reduced electronic conductivity and loss of effective active particles. Furthermore, great effort has been made to push the charge cutoff voltage higher than 4.5 V to approach the theoretical capacity, which aggravates the structural, interfacial, and thermodynamic instabilities of NMC811.

In H3 phase, the delithiated NMC811 are thermodynamically unstable. They can either chemically oxidize electrolyte solvents or spontaneously release oxygen. The dissolved oxygen may crossover through the separator, reach the anode, and chemically react with the lithiated anode (e.g., graphite in LIBs). Such a reaction is far more energetic than the reaction with electrolyte solvents and may lead to thermal runaway of LIBs. Thus, stabilizing the H3 phase is the key to increase the safety of NMC cathodes. In addition, the electrochemical reduction of the dissolved transition metal ions (M²⁺) and the generated CO₂ on the anode irreversibly consumes Li⁺ ions from the cathode, which consequently reduces the cathode/anode capacity ratio. As such, the cathode could get overcharged, triggering safety issues (e.g., fire accidents) even when a battery is charged in the normal voltage range.

Besides the many issues related to oxygen release discussed above, there are also issues caused by RLCs. RLCs are inevitably present on the surface of NMCs and mainly in forms of LiOH and Li₂CO₃. Their amount increases with the increasing Ni content, and they could cause battery swelling (gassing) during cycling. In addition, RLCs are prone to cause NMC electrode structural instability. The typical electrode binder, poly (vinylidene fluoride) (PVDF), is particularly vulnerable to the basicity of LiOH and Li₂CO₃. Specifically, RLCs degrade PVDF by dehydrofluorination and cause “slurry gelation” during electrode production. Consequently, RLCs lead to poor performance of NMCs. This issue is much more severe for NMC811, due to more RLCs generated on its surface.

Various strategies have been adopted to tackle these afore-discussed issues of NMCs. Among them, several widely used methods are: (1) elemental doping; (2) addition of electrolyte additives; and (3) surface coating. These strategies are aimed at reconstructing either the surface (i.e., the interface between NMCs and electrolytes) or the bulk structure of NMCs.

Elemental doping has been used to modify and stabilize the bulk structure of NMCs. The modified NMCs can mitigate the Ni/Li cationic mixing and thereby enable an improved electrochemical performance. Many dopants have been investigated and classified as cations (e.g., Na⁺, K⁺, Mg²⁺, B³⁺, Al³⁺, Si⁴⁺, Ti⁴⁺, Zr⁴⁺, Ta⁵⁺, and W⁶⁺) or anions (e.g., F⁻, S²⁻, and P⁵⁻).Different working mechanisms have been proposed for these dopants: (1) substituting mobile ions (e.g., Ni²⁺and Li⁺) with structurally and electrochemically static ions; (2) hindering Ni²⁺ions from migration to Li⁺ layers; (3) increasing the bond strength of TM-O and thereby alleviating oxygen release. In addition to enhancing the structural stability of NMCs, elemental doping may also improve cationic diffusion and electronic conductivity. However, the dopant concentration should be finely tuned, for a higher dopant content could lead to detrimental effects.

Electrolyte additives, different from elemental doping, are deployed to construct a stable artificial SEI between NMCs and electrolytes, which prevents side reactions and lowers cell impedance. To date, a large variety of additives has been studied and some widely used ones are vinylene carbonate (VC), vinylethylene carbonate (VEC), triphenylphosphine oxide (TPPO), fluoroethylene carbonate (FEC), lithium bis (oxalate) borate (LiBOB) and 1,3-propane sultone (PS). The resultant SEI by these additives reduced metal dissolution and interfacial reactions and thereby contributed to better performance, accounting for a slower degradation rate of the capacity of NMCs. However, in many cases, the additives more or less introduce other negative impacts while improving the performance in some respects.

Surface coating as a strategy, compared to both elemental doping and electrolyte additives, is more facile and straightforward. Through applying a layer of a desirable material on NMCs, surface coating isolates NMCs from contacting with electrolytes, reduces undesirable reactions at interfaces, and mitigates decomposition of electrolytes. Traditionally, surface coating has been dominantly performed on battery powders via wet chemistry (e.g., sol-gel processes) prior to electrode fabrication. A large variety of coatings have been practiced via wet chemical methods, including elements (e.g., Ag), Li-free oxides (e.g., Al₂O₃, ZrO₂, and TiO₂), Li-containing oxides (LiBO₂, LiNbO₃, and Li₂MnO₃), phosphates (e.g., Li₃PO₄, AlPO₄, and FePO₄), fluorides (e.g., MgF₂ and PrF₃), and others. Coating films via wet chemistry are usually non-uniform and thick, ranging from several tens to several hundreds of nanometers.

In the past decade, atomic layer deposition (ALD) as a novel vapor-phase technique has emerged as a technology for surface coating of LIBs and has shown many unique capabilities over wet chemistry. Consequently, ALD has offered many novel technical solutions to challenges in batteries.

ALD is a technique for surface coating of LIBs, featuring a series of distinguished capabilities: (1) atomic-scale precise controllability over film thickness, ranging from sub-nano to nano scale, (2) uniform and conformal coverage, (3) low deposition temperature (room temperature to 200° C.), and (4) processable on either prefabricated electrodes or electrode powders. All these exceptional capabilities are owing to ALD's unique growth mechanism. Mechanistically, ALD is a surface-controlled process relying on cyclic self-limiting gas-solid surface reactions to proceed material growth. Each gas-solid reaction produces only one atomic layer, and one cycle consists of two or more surface reactions. Thus, ALD performs a layer-by-layer growth of materials with repeatable cycles. The growth per cycle (GPC) is typically ˜1 Å/cycle. Consequently, the unique growth mechanism and the resultant excellent capabilities distinguish ALD from its traditional counterparts such as physical and chemical vapor deposition (i.e., PVD and CVD).

To illustrate the ALD mechanism, FIG. 4 exemplifies a process of ZnS using diethyl zinc (DEZ) as the metal precursor and H₂S as the sulfur precursor. The overall reaction is:

Zn(C₂H₅)₂+H₂S→ZnS+2C₂H₆ (1)

In the ALD process of ZnS, the overall reaction is divided into two sequential half-reactions:

|-SH+Zn (C₂H₅)₂(g)→|-S—Zn—C₂H₅+C₂H₆ (g) (2A)

|-S—Zn—C₂H₅+H₂S(g)→|-S—Zn—SH+C₂H₆ (g) (2B)

where “|-” represents the substrate surface and “g” denotes the gas phase of the precursors (i.e., DEZ and H₂S) and the byproduct (C₂H₆). During the ZnS growth process of ALD, the first half-reaction (step 1-2 in FIG. 4) occurs between DEZ and surface function groups of —SH, and it produces a new layer of—ZnC₂H₅ bounded to sulfur with the release of C₂H₆ as the byproduct. The second half-reaction (step 3-4 in FIG. 4) is between —ZnC₂H₅ and H₂S, and it restores the substrate surface back to a full coverage of —SH with the rest release of C₂H₆ as the byproduct. After the second half reaction, the substrate surface is covered by one layer of ZnS and ready for another cycle of ZnS growth. Thus, ALD is operated in a cycle-by-cycle manner. These two half-reactions individually proceed and terminate automatically once their surface reactive sites (either -SH or —ZnC₂H₅) deplete. To ensure no direct reactions between DEZ and H₂S, a fully thorough purge is applied after each half-reaction. By taking these time-dependent growth procedures, ALD enables the ZnS growth under an accurate control at the atomic level (˜1 Å/cycle). Previously, ALD has enabled uniform coatings on wafer-scale planar substrates and conformal coatings over ultrahigh aspect-ratio nanoporous templates up to 10000:1. ALD has deposited a large variety of inorganic materials, widely covering elements, oxides, sulfides, nitrides, fluorides, and complex compounds.

ALD enables many novel solutions in many applications. In the past decade, there has been increasing interest in ALD for LIBs and beyond. Compared to wet chemistry (FIG. 5a), ALD is more flexible and more accurate for surface modification. ALD can enable high-quality conformal nanofilms (typically <5 nm) with an accuracy of ˜1 Å while wet chemistry is not accurate in film quality and usually leads to thick non-uniform films ranging from several tens to several hundreds of nanometers. To modify batteries, ALD can be practiced in three different strategies. First, ALD as a vapor-phase process is to date the only technique capable of coating prefabricated electrodes directly. This strategy is named as ALD_{E}, as illustrated in FIG. 5b. As shown in FIG. 6, coating 500, which may be Li₂S, is applied to cathode 510.

Alternatively, ALD can first coat conformal films over powder-based electrode materials and then the coated powders are further fabricated into electrodes. This second strategy is named as ALD_{P}, as illustrated in FIG. 5c. Furthermore, the ALD_{P} strategy can combine with a post-annealing process to further optimize the coated powder surface and then the annealed coated powder can be fabricated into electrodes. This third strategy is named as ALD_{P}-T, as illustrated in FIG. 5d. Consequently, ALD has enabled some irreplaceable capabilities.

In case of NMCs, a variety of ALD coatings has been investigated, including oxides (Al₂O₃, TiO₂, ZrO₂, ZnO, MgO, and LiₓTi_{y}O), fluorides (AlF₃, AlF₃/AlWₓF_{y}, and LiAlF₄), nitrides (TiN), and phosphates (Li₃PO₄, AlPO₄, TiPO, and TiPON). These coatings were applied via ALD_{E}, ALD_{P}, or ALD_{P}-T. In general, these ALD coatings have improved the mechanical properties of NMC811, mitigated microcracking, inhibited HF attacks, and thereby alleviated oxygen release. Consequently, all these coatings have enhanced the performance of NMCs but differed in their improvement capabilities, mainly due to their different properties and their different synergic effects with NMCs. Despite the improvements, these coatings have not ultimately addressed the issues of NMCs. For example, RLCs were still present on the surface of NMCs while oxygen still could release from lattices of NMCs even at a reduced amount. Consequently, cell failures eventually occurred through a gradually aggravated degradation process.

To maximize the cell lifetime of NMC811, thus, it is essential to minimize the oxygen release from the lattices of NMCs and clean RLCs away from the surface of NMCs. To this end, innovative technologies are urgently needed.

### BRIEF SUMMARY OF THE INVENTION

In one embodiment, the present invention concerns using sulfides that can improve the performance of cathodes in lithium-ion batteries or lithium metal batteries. It was found that sulfide coatings are multifunctional in protecting cathodes from degradation, including reducing side reactions, improving mechanical integrity, and mitigating structural phase transitions. Sulfide coatings are an effective way to improve cathodes' performance in rate capability, long-term cyclability, capacity retention, and structural stability.

In other embodiments of the present invention, a method is provided wherein, via a desirable ALD_{P}-T strategy, sulfide coatings not only form a reinforcement layer over NMC811 to improve its mechanical properties and thereby to minimize micro-cracking and the oxygen release, but also react with the released oxygen and RLCs to form a sulfate coating to protect electrolytes from oxidation (i.e., decomposition), improve electrode structural stability, and facilitate the transport of Li-ions. All these are very compelling for ultimately addressing the issues of NMC811 and accelerating its commercialization to boost the EV market as well as other markets.

The embodiments of the present invention may be used in developing next-generation high-energy lithium-ion batteries and lithium metal batteries. The present invention will be able to deliver new rechargeable batteries with higher energy density, longer lifetime, improved safety, and reduced cost. The resultant batteries can be used for portable electronics, electric vehicles, and smart grids.

### BRIEF DESCRIPTION OF THE SEVERAL VIEWS OF THE DRAWINGS

In the drawings, which are not necessarily drawn to scale, like numerals may describe substantially similar components throughout the several views. Like numerals having different letter suffixes may represent different instances of substantially similar components. The drawings illustrate generally, by way of example, but not by way of limitation, a detailed description of certain embodiments discussed in the present document.

FIG. 1 shows the specific capacity and energy density of the main cathodes of LIBs, including LCO, LMO, LFP, NCA, and NMC811 .

FIGS. 2A, 2B and 2C show the morphology and phase transitions of NMC811 . Typically, (A) a microscale secondary particle of NMC811 consists of many (B) nanoscale primary particles. (C) The typical profile of differential capacity versus cell voltage in Li/NMC811 half cells.

FIG. 3 shows NMC microcracking: (A) NMC secondary particles, (B) unit cell volume change during charge-discharge processes, (C) formation of microcracking, including intergranular and intragranular cracks, and (D) electrolyte penetration into cracks and decomposition with the formation of NiO-like phase.

FIG. 4 is an illustration of an ALD process, which is exemplified by ZnS using precursors of DEZ and H₂S.

FIG. 5 shows the surface modifications via wet chemistry and ALD: (A) wet chemistry, (B) ALD directly applied on prefabricated electrodes, i.e., ALD_{E}, (C) ALD applied on electrode powders, i.e., ALD_{P}, and (D) ALD_{P} combined with a post-annealing process at a certain temperature, i.e., ALD_{P}-T.

FIG. 6 shows the ALD_{E} strategy of Li₂S on NMC cathodes and the conversion of the Li₂S coating to lithium sulfates (LiₓS_{y}O) during electrochemical cycles.

FIGS. 7A, 7B and 7C show the beneficial effects of the ALD Li₂S coating via ALD_{E}. (A) Rate capability, (B) long-term cyclability, and (C) discharge voltage stability of the bare and Li₂S-20E (i.e., the electrodes coated by 20-cycle ALD Li₂S via ALD_{E}) electrodes.

FIGS. 8A and 8B show the morphological evolutions of cycled NMC811 . (A) scanning electron microscopy (SEM) and (B) transmission X-ray microscopy (TXM) images of the bare and Li₂S-20E electrodes after 500 charge-discharge cycles.

FIGS. 9A, 9B, 9C and 9D show the structural analyses of NMC811 . Focus ion beam (FIB)-SEM images of the cross-sections of (A) bare (C) Li₂S-20E secondary particles after cycling. High-resolution transmission electron microscopy (HR-TEM) images of (B) bare (D) Li₂S-20E primary particles after cycling.

FIGS. 10A and 10B show the surface analyses of NMC811. High-resolution X-ray photoelectron spectroscopy (XPS) spectra of S 2p and Li 1s of (A) pristine Li₂S film and (B) the cycled Li₂S-20E electrode after 20 charge-discharge cycles.

FIG. 11 shows the first charge-discharge profiles of NMC622 without and with ALD coatings of Al₂O₃, ZrO₂, and LiₓZr_{y}O via ALD_{E}. In all the cases, there has an evident voltage spike at the early stage of the charge profiles.

FIGS. 12A, 12B, 12C and 12D show the effects of Li₂S coating via ALDₚ-T on NMC811 electrodes: (A,B) The first charge-discharge profiles, (C) cyclability, and (D) rate capability of NMC electrodes. These results show that a desirable annealing is critical for the ALD_{P}-T strategy of NMC811 to achieve the best performance.

FIGS. 13A and 13B show the effects of ZrS₂ coating on NMC811 via ALD_{E}. (A) the first charge-discharge profiles and (B) long-term cyclability of bare and Zr₂S-coated NMC811 electrodes with different ALD cycles (5, 10, 20, and 40).

FIG. 14 shows an approach to reconstruct the desirable surface via ALD_{P}-T and multiple charge-discharge cycles. (A) The pristine NMC powders with inter-granular cracks in their bulks and Li₂CO₃ on their surface, (B) ALD is applied on these powders to form a conformal metal sulfide coating, (C) an annealing process is performed on the metal-sulfide-coated NMC powders, which diffuses metal sulfides into granular cracks, reconstructs the near surface by elemental doping, and converts sulfide-coated Li₂CO₃ into Li₂O and MₓSO₃, and (D) surface reconstruction is eventually finished after multiple charge-discharge cycles, which features a surface of LiₓM_{y}SO₄ and a reconstructed near-surface.

FIGS. 15A and 15B show SEM images of NMC electrodes: (A) SEM images of uncoated and Li₂S-coated NMC electrodes and (B) The EDS mapping of the ALD-20 electrode.

FIGS. 16A, 16B and 16C show (A) Rate capability of uncoated and Li₂S coated NMC811 at various current densities in a voltage range of (i) 3.0-4.3 V, (ii) 3.0-4.5 V, (iii) 3.0 -4.7 V. (B) Normalized average capacity of ALD-0 (bare) and ALD-20 (i.e., Li₂S-20E) versus rates in a voltage range of (i) 3.0-4.3 V, (ii) 3.0-4.5 V, (iii) 3.0-4.7 V. (C) Cyclability (charge at 0.5 C and discharge at 1 C) and Coulombic efficiency of ALD-0 and ALD-20 electrodes at 3.0-4.3 V.

FIGS. 17A and 17B Cyclability (charge at 0.5 C and discharge at 1 C) of ALD-0 (bare) and ALD-20 (i.e., Li₂S-20E) (A) at 3.0-4.5 V, (B) at 3.0-4.7 V

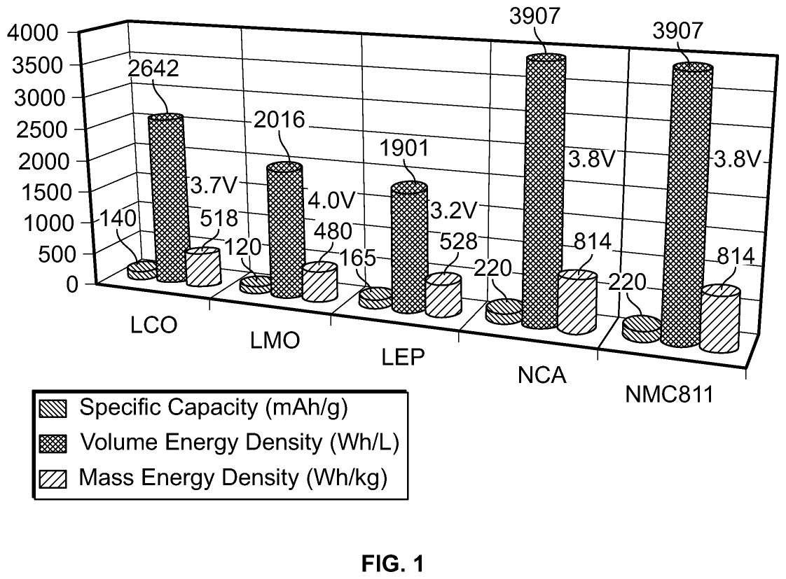

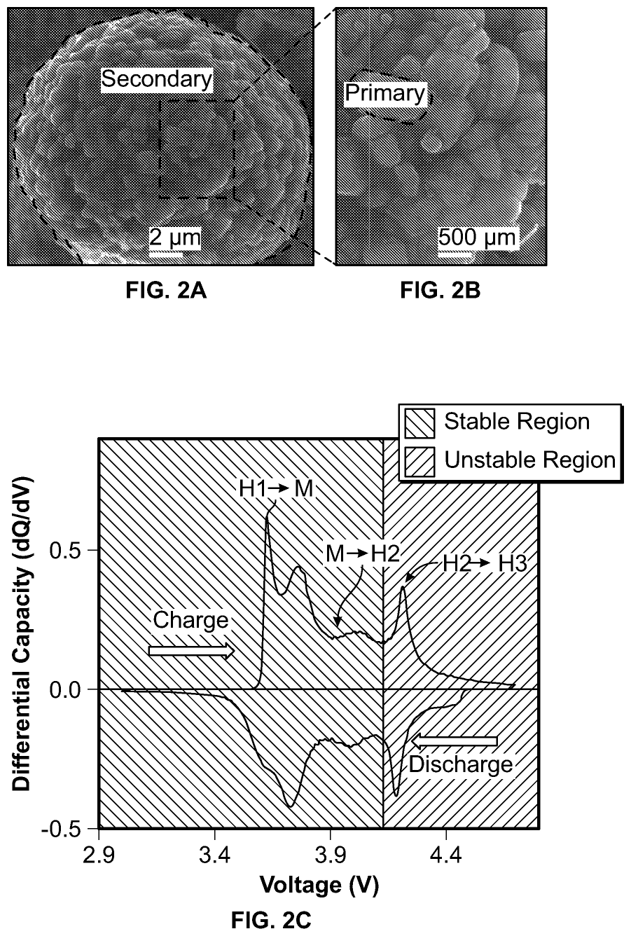

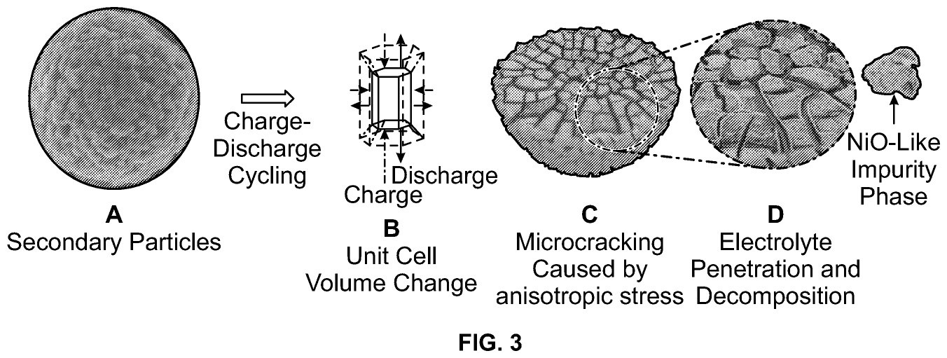

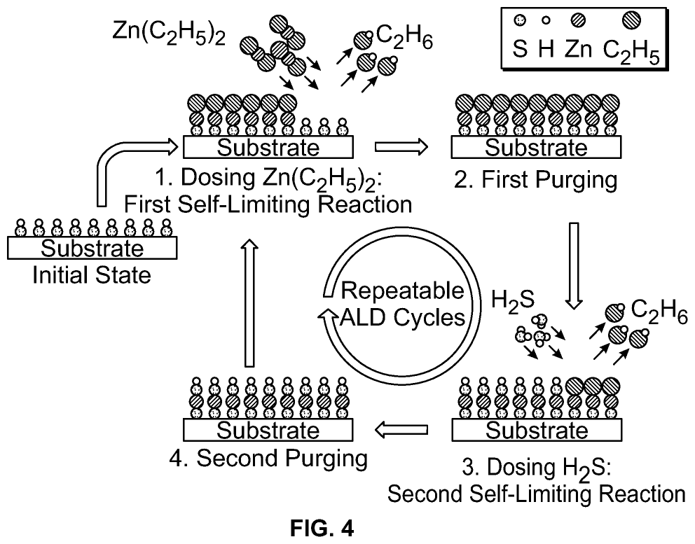

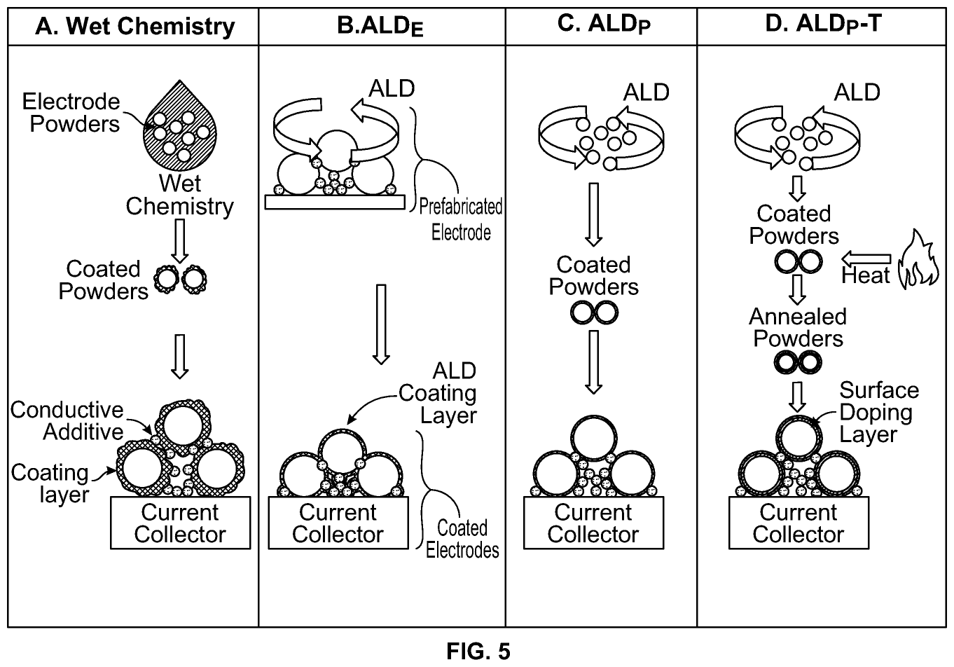

### DETAILED DESCRIPTION OF THE INVENTION

Detailed embodiments of the present invention are disclosed herein; however, it is to be understood that the disclosed embodiments are merely exemplary of the invention, which may be embodied in various forms. Therefore, specific structural and functional details disclosed herein are not to be interpreted as limiting, but merely as a representative basis for teaching one skilled in the art to variously employ the present invention in virtually any appropriately detailed method, structure or system. Further, the terms and phrases used herein are not intended to be limiting, but rather to provide an understandable description of the invention.

The embodiments of the present invention take advantage of the beneficial effects of sulfides using an Li₂S coating on NMC811 via ALD_{E}, ALD_{P}, and ALD_{P}-T wherein the Li₂S coatings play the following roles:

First, the Li₂S coating is not only able to serve as a reinforcement layer to strengthen the mechanical properties of NMCs but also acts as an O₂-scavenger to consume released oxygen and thereby protect electrolytes from any oxidation-related decomposition.

This can be realized by ALD_{E}, ALD_{P}, or ALD_{P}-T. The reactions between Li₂S and O₂ are as follows:

2Li₂S+3O₂→2Li₂SO₃ (3)

2Li₂SO₃+O₂→2Li₂SO₄ (4)

Second, the Li₂S coating appear to react with RLCs at a certain temperature and thereby contribute to a clean surface. This can only be achieved by ALDₚ-T. The potential reactions are postulated as follows:

Li₂S+3Li₂CO₃→Li₂SO₃+3Li₂O+3CO (g) (5)

2LiOH→Li₂O+H₂O (6)

Li₂SO₃+Li₂O−2e⁻→Li₂SO₄+2Li⁻ (7)

Third, the Li₂S coating contributes to S-doping into the near surface of NMC811 at a certain temperature and thereby reconstructs the near surface structure. This can only be realized by ALD_{P}-T. The S-doped near surface facilitates the transport of Li⁺ ions, due to the larger ion radius of S²⁺.

Li₂MO₂+xLi₂→Li₂₊ₓMSₓO₂ (8)

Based on the above, the embodiments of the present invention provide a robust, clean, and antioxidative surface of NMC811, which is able to inhibit microcracking, oxygen release, TM dissolution, irreversible phase transition, and electrolyte decomposition. This results in an Li₂S-coated NMC811 having a long-term stable cyclability.

Li₂S nanofilm is an O₂-scavenger as well as a reinforcement layer via ALD_{E}.

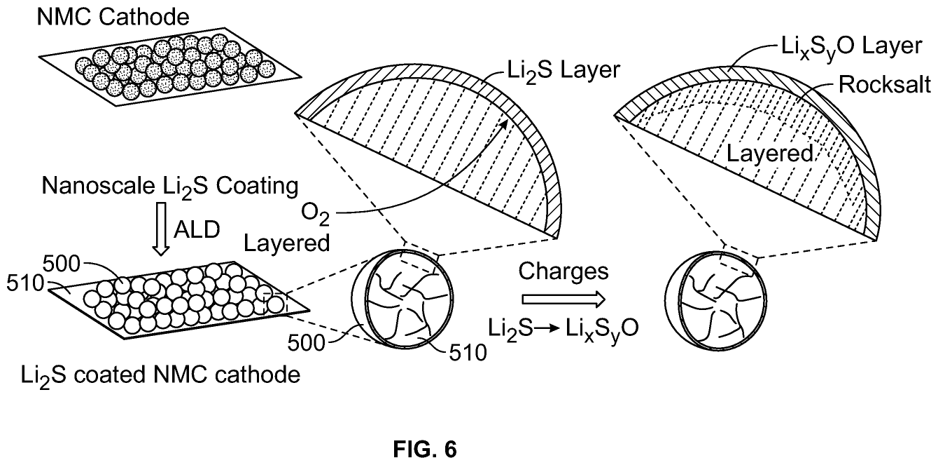

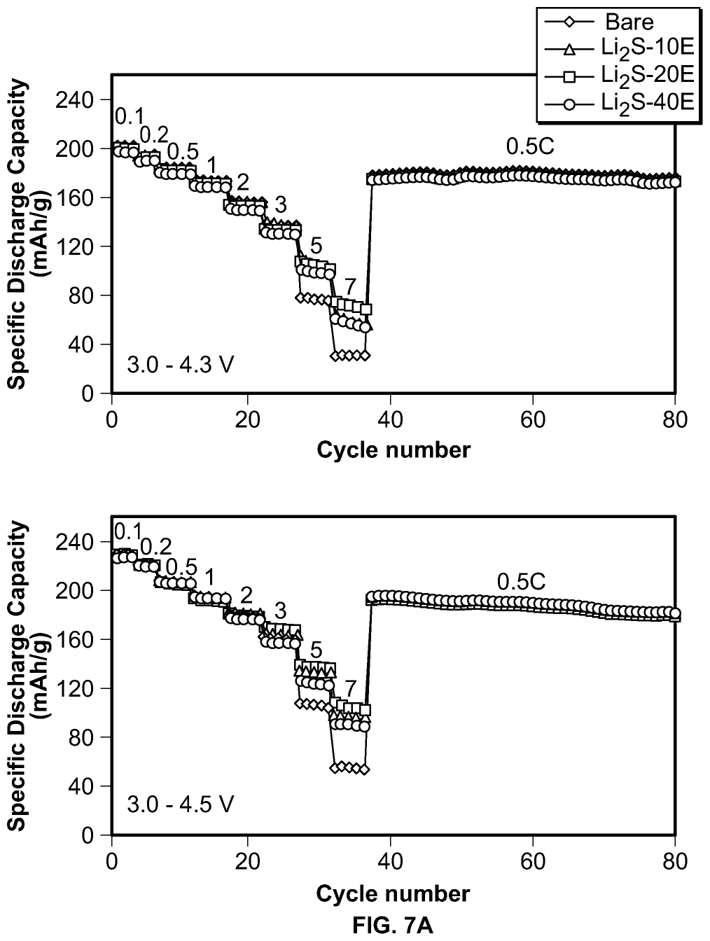

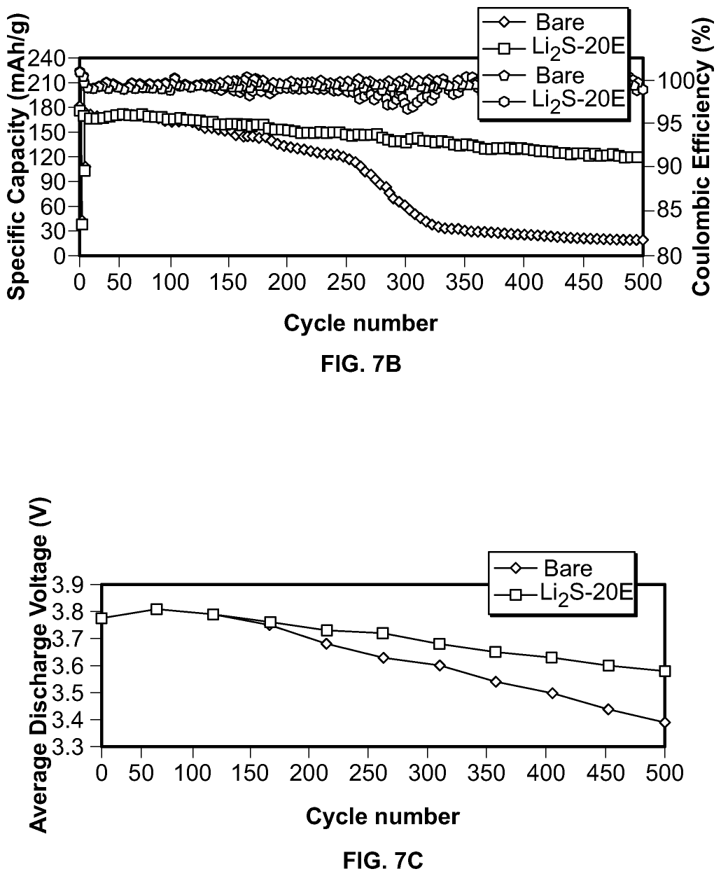

As stated above, ALD uniquely enables surface coatings via ALD_{E} and ALD_{P}. The ALD_{E} method is facile and a good option to verify the roles of the Li₂S coating as a reinforcement layer and an O₂-scavenger. To do so, prefabricated NMC811 electrodes were coated with Li₂S films of different thicknesses through adjusting ALD cycles (10, 20, land 40) via ALD_{E} (FIG. 6). Then, the coated electrodes were named as Li₂S-10E, 20E, and 40E, respectively. It was found that, compared to the bare electrodes, these Li₂S-coated electrodes enabled better rate capabilities in the voltage ranges of 3.0-4.3/4.5 V while the Li₂S-20E electrode showed the best rate capability (FIG. 7A). It was also revealed that the Li₂S-20E could distinctly beat the bare electrode, accounting for long-term cyclability, high sustainable capacity, and stable Coulombic efficiency (FIG. 7B). In addition, the discharge voltage of Li₂S-20E electrode dropped much slower than that of the bare electrode with cycling (FIG. 7C). This shows that Li₂S coatings via ALD_{E} improve the performance of the NMC811 electrode.

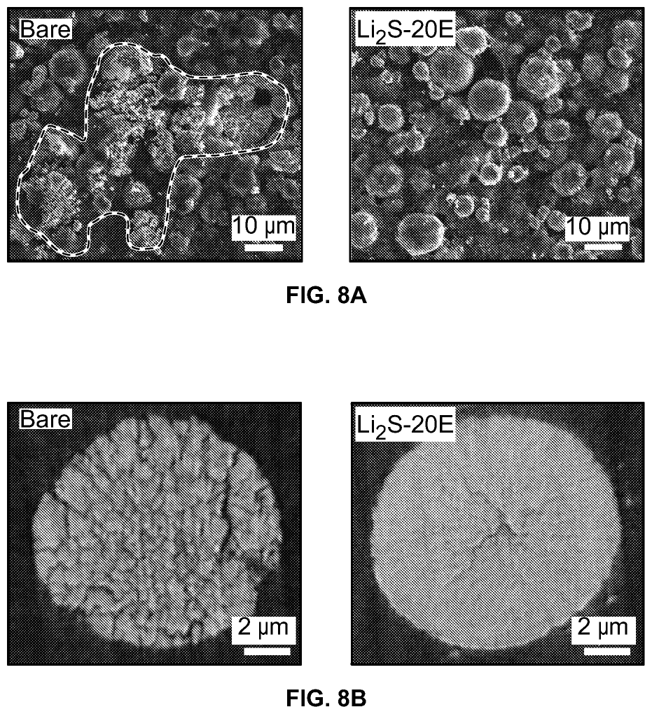

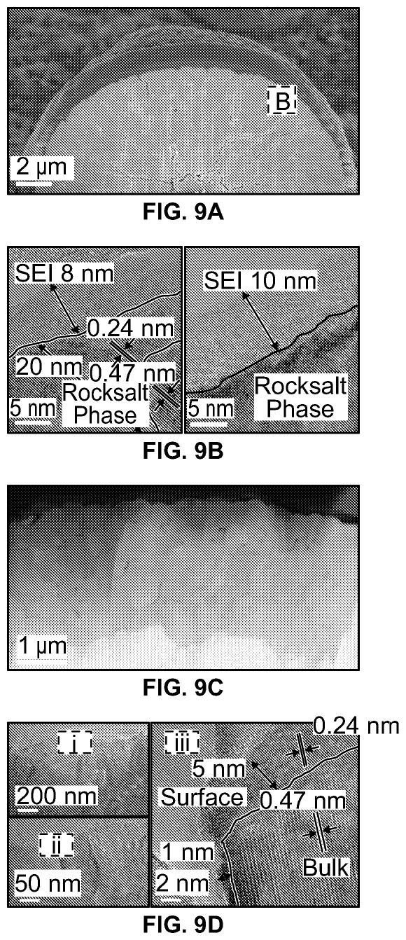

Scanning electron microscopy (SEM) images show that a large amount of bare NMC particles broke into small particles and peeled off from the bare electrode while there was no change observed from the Li₂S-20E electrode (FIG. 8A). Transmission X-ray microscopy (TXM) images also verified that secondary particles of the cycled bare electrode have a large number of evident cracks, but the secondary particles of the cycled Li₂S-20E electrode only have some minor cracking (FIG. 8B). Using focus ion beam SEM (FIB-SEM), it was further confirmed that the cycled bare electrode has serious microcracking (FIG. 9A) while the cycled Li₂S-20E only have some minor cracking (FIG. 9C). Using high-resolution transmission electron microscopy (HR-TEM), it was noticed that, after 500 charge-discharge cycles, the cycled bare NMC particles have experienced remarkable phase transition from the initial layered structure to the NiO-like rocksalt structure on their surface, up to 20 nm thick (FIG. 9B). In addition, there is a thick layer of SEI formed on the cycled bare NMC particle surface, up to 10 nm thick. In contrast, the cycled Li₂S-20E NMC particles have much less layered-rocksalt transition (5 nm at most) and little SEI on their surface (FIG. 9D). All these results clearly indicate that the Li₂S coating have remarkably enhanced the mechanical integrity of NMC particles, dramatically mitigated microcracking, evidently inhibited irreversible layer-rocksalt phase transition, and well protected the electrolyte from decomposition and SEI formation.

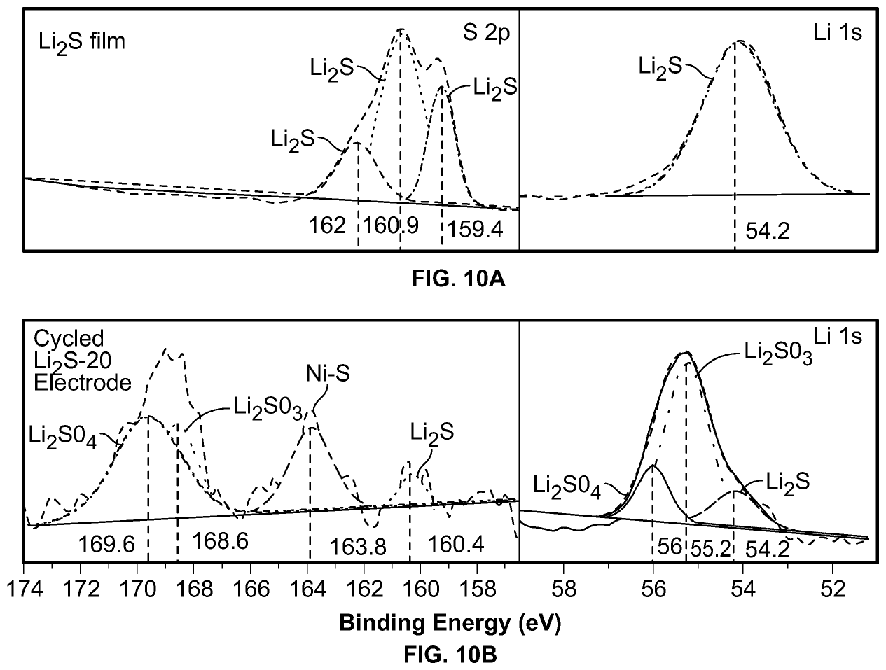

Significantly, it was further discovered that the Li₂S coating experienced a transformation, in which it has nearly converted into LiₓS_{y}O (i.e., Li₂SO₃ and Li₂SO₄) completely after 20 charge-discharge cycles (FIG. 10). This has further confirmed the role of the Li₂S coating as an O₂-scavenger, i.e., 2Li₂S+3O₂→2Li₂SO₃; 2Li₂SO₃+O₂→2Li₂SO₄. The Li₂S coating provides a route to tackle the released O₂ from the NMC lattices and thereby to protect the electrolyte from decomposition. This avoids many undesirable effects due to the electrolyte decomposition and extends the lifetime of NMC electrodes. Additionally, the LiₓS_{y}O compounds are electronically insulating but have better ionic conductivity than that of Li₂S.

The Li₂S nanofilm can remove RLCs to constitute a clean surface of NMC811 via ALD_{P}-T.

As for RLCs on the surface of NMC811 , both LiOH and Li₂CO₃ are detrimental to the electrochemical performance. Their basicity can cause the degradation of PVDF, i.e., “slurry gelation”. The deterioration of PVDF can vary the slurry microstructure and lead to catastrophic issues of NMC811. Li₂CO₃ impedes ionic and electronic transport to the underlying electrode. To achieve high performance, thus, it is essential to remove both LiOH and Li₂CO₃ from NMC811. Previous studies have revealed that the decomposition of LiOH and Li₂CO₃ starts from ˜250 and ˜600° C., respectively. Apparently, it is more challenging to decompose Li₂CO₃.

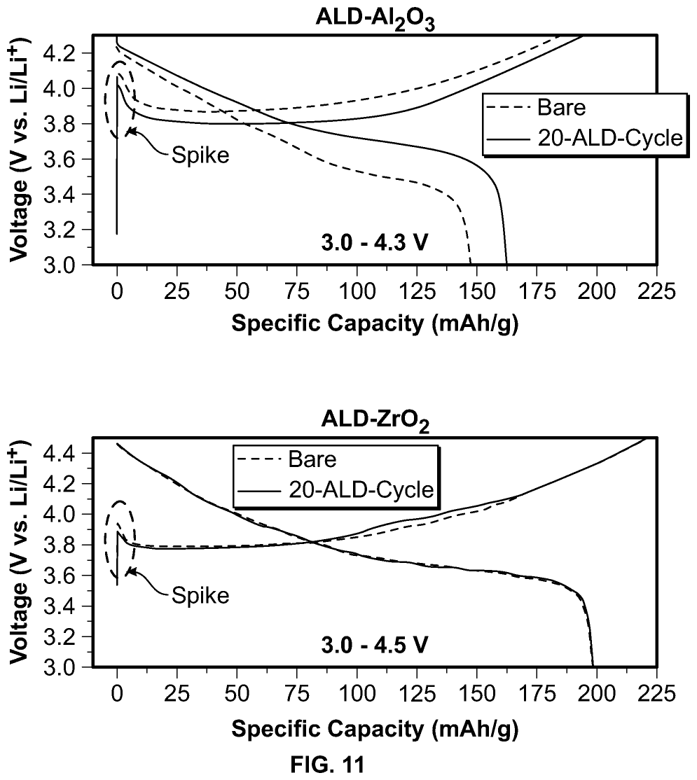

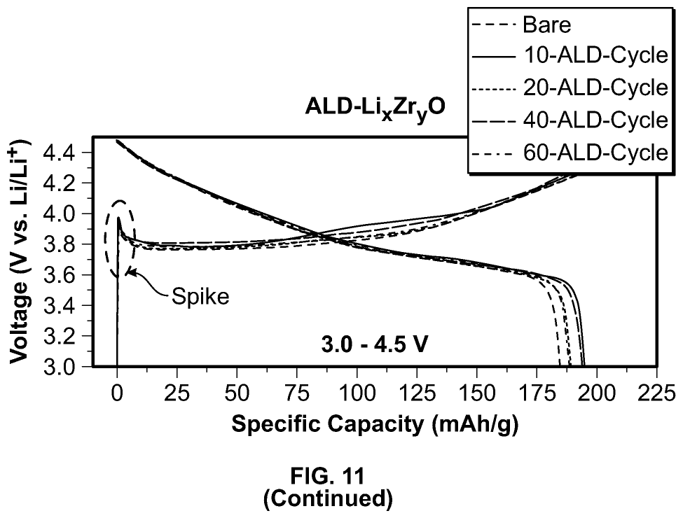

Li₂CO₃ on the surface of NMCs commonly causes a steep increase (i.e., a spike) of the voltage in the early state of the charge. It was also found that oxide coatings (e.g., Al₂O₃, ZrO₂, and LiₓZr_{y}O) via ALD_{E} could not suppress the undesirable effects of the surface Li₂CO₃, for the spike induced could always be observed (FIG. 11).

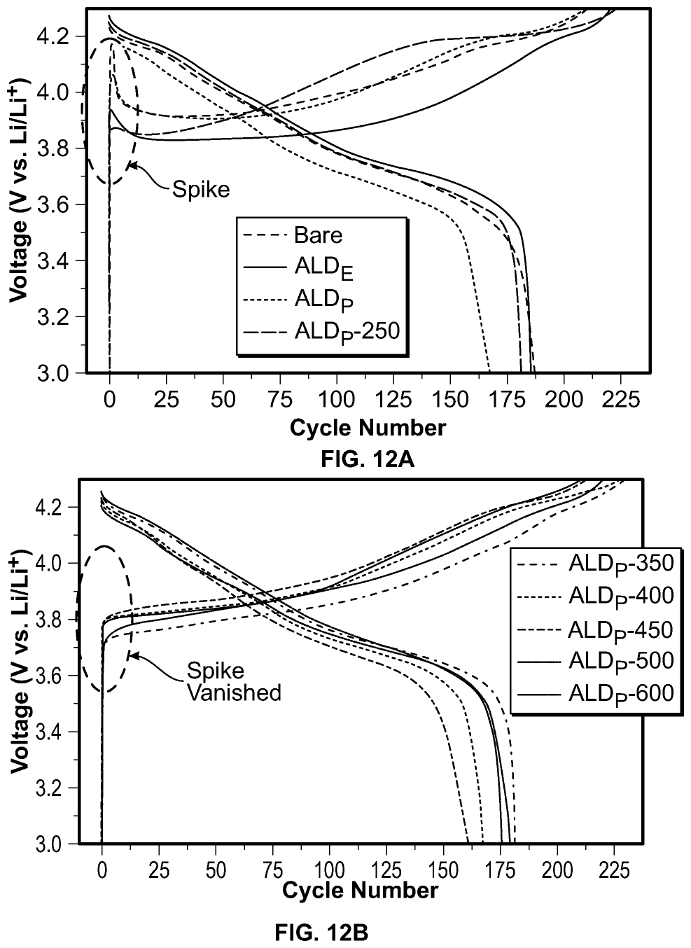

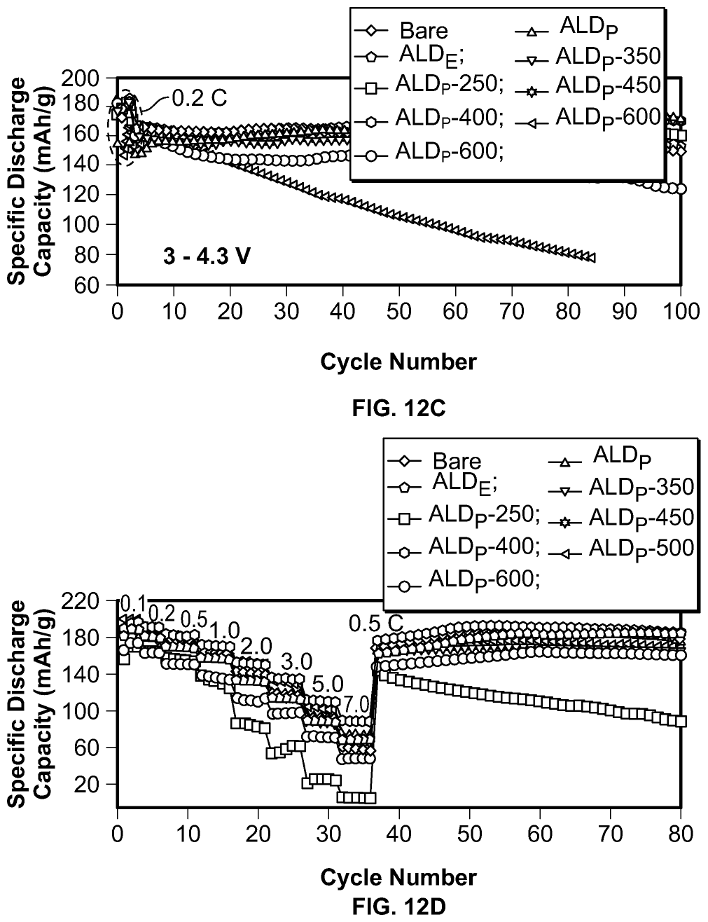

The NMC811 electrodes via ALD_{P}-T are differentiated by their annealing temperature. For example, ALD_{P}-100 indicates that the Li₂S-coated NMC811 powders were further annealed at 100° C. for 5 hours and the resultant annealed Li₂S-coated NMC811 powders were made into electrodes. It was found that, same to the bare NMC811 electrode, both the NMC811 electrodes via ALD_{E} and ALD_{P} also exhibited voltage spikes (FIG. 12a); that is, the 20-ALD-cycle Li₂S coating could not remove Li₂CO₃ from the surface of NMC811 at room temperature. Applying the ALD_{P}-T strategy, it was found that a 5-hour annealing at 250° C. could not fully remove the spike but remarkably reduced the intensity (FIG. 12A). Encouragingly, a 5-hour annealing at 350° C. or higher could fully remove the spike (FIG. 12B); that is, the Li₂S coating could help clean Li₂CO₃ from the surface of NMC811 at a much lower temperature than that of the thermal decomposition of Li₂CO₃. This is significant, for it verified the role of the Li₂S coating as a remover of RLCs, i.e., the Li₂S helps remove RLCs for securing a clean surface via ALD_{P}-T. The performance of these electrodes via ALD_{E}, ALD_{P}, and ALD_{P}-T was further investigated. According to testing for long-term cyclability (FIG. 12C) and rate capability (FIG. 12D), it seems that there exists an optimal temperature to achieve the best electrochemical performance, which is in the range of ˜350-400° C. From FIG. 12C it may be concluded that the cyclability of both the ALD_{P}-400 and ALD_{P}-350 electrodes is much better than that of the other electrodes, accounting for a sustainable capacity of ˜170 mAh/g vs. ˜150 mAh/g of the bare NMC811 electrode after 100 charge-discharge cycles at 1 C (1 C=220 mA/cm²). At increased current rates (FIG. 12D), furthermore, both the ALD_{P}-400 and ALD_{P}-350 electrodes enabled the highest capacity among all the electrodes, i.e., ˜150, ˜140, ˜110, and ˜90 mAh/g at 2, 3, 5 and 7 C, respectively. In comparison, the bare NMC electrode's capacity was ˜140, ˜120, ˜95, and 60 mAh/g at 2, 3, 5 and 7 C, respectively. The better rate capability of the ALD_{P}-400 and ALD_{P}-350 electrodes indicates their better interface. This can be partially attributed to the removal of Li₂CO₃ and LiOH. Additionally, the better rate capability might be related to some S-doping into the near surface of NMC811 to constitute a better near-surface structure facilitating the transport of Li⁺ ions. This is related to the role of the Li₂S coating as the doping source of S at certain temperatures.

To summarize, the Li₂S coatings via ALD_{P}-T of the present invention have the following benefits on NMC811 :
(1). A reinforcement layer to minimize the evolutions of microcracking and thereby to suppress O₂ release, irreversible phase transition, and TM dissolution.
(2). A remover of RLCs to eliminate the detrimental effects of Li₂CO₃ and LiOH, which protects PVDF from degradation.
(3). An antioxidative film to scavenge O₂ released from the NMC811 lattices, which protects the electrolyte from the attack of O₂ and thereby helps avoid many subsequent unfavorable reactions.
(4). An artificial SEI layer to stabilize the interface between NMC811 and the electrolyte, which minimize parasitic reactions and TM dissolution
(5). A dopant source (metal cations and sulfur anions) to the surface-near lattices to attenuate Ni/Li cationic mixing, which helps reconstruct a new near-surface facilitating the transport of Li⁺ ions.

Compared to ALD_{E} and ALD_{P}, the ALD_{P}-T strategy reconstructs a robust, clean, and antioxidative surface to address the issues of NMC811. With the reconstructed surface, the resultant cathodes may achieve much higher performance than that of the bare, ALD_{E}, and ALD_{P} NMC811 cathodes, in terms of sustainable capacity, cyclability, rate capability, and Coulombic efficiency.

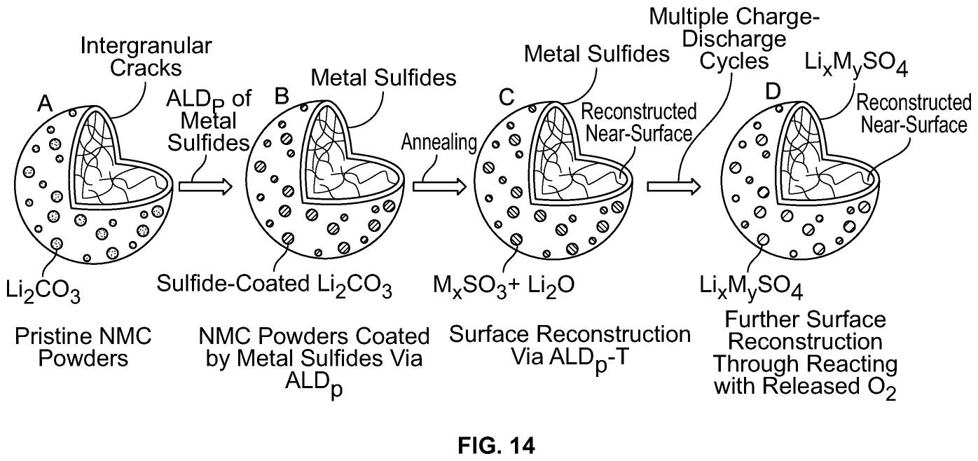

The ALD_{P}-T strategy of sulfides consists of three steps:
Step 1: Pristine NMC811 powders are coated conformally with the proposed metal sulfides via ALD_{P} (FIG. 14A and 14B). The coating thickness can be accurately tuned to optimize the coatings' effects on NMC811′s performance. RLCs on the NMC surface are fully wrapped by the metal sulfide coatings.
Step 2: Applying an annealing process on the sulfide coated NMC811 powders (FIG. 14C). This step is critical for reconstructing the surface of NMC811 powders. Under an optimal temperature, metal sulfides can diffuse into the intergranular cracks to further reinforce the powder mechanically. Under this optimal temperature, the near surface of NMC811 powders may be reconstructed by elemental doping. For example, metal sulfides of Li₂S, Al₂S₃, and ZrS₂ are the dopant sources of Al³⁺, Zr⁴⁺, and S²⁻. The doped near surface of NMC powders is more stable and enables a better ionic conductivity of Li⁺ ions. Furthermore, Li₂CO₃ reacts with the sulfide coatings (e.g., Li₂S, Al₂S₃, and ZrS₂) with the production of Li₂O and MₓSO₃ (M=Li⁺, Al³⁺, and Zr⁺⁴).
Step 3: The reconstructed surface is further evolved under charge-discharge cycles (FIG. 14D). During the charge-discharge cycles, there may be some O₂ released. Then, the released O₂ reacts with the metal sulfide coatings and converts them into LiₓM_{y}SO₄ during delithiation (charge) and lithiation (discharge) process of NMC811. During these processes, the near surface is also expected to further evolve into a more stable structure. The RLCs are eventually converted into LiₓM_{y}SO₄. All these jointly result in a fully reconstructed surface. The reconstructed surface features its robust, clean, and antioxidative nature and contributes to remarkably improved performance of NMC811.

It was discovered that the embodiments of the present invention are not limited to Li₂S, many other O₂-reactive sulfides may be used as surface coatings of NMCs as well, including Na₂S, K₂S, Rb₂S, Cs₂S, Fr₂S, BeS, MgS, SrS, BaS, RaS, Sc₂S₃, Y₂S₃, TiS₂, ZrS₂, HfS₂, V₂S₅, Nb₂S₅, Ta₂S₅, CrS₂, MoS₂, WS₂, MnS, MnS₂, TcS₂, ReS₂, Fe₂S₃, Ru₂S₃, Os₂S₃, CoS, CoS₂, Co₃S₄, Co₉S₈, RhS, RhS₂, NiS, NiS₂, PdS, PdS₂, PtS, PtS₂, CuS, Cu₂S, Ag₂S, AgS, Au₂S, AuS, ZnS, CdS, HgS, B₂S₃, Al₂S₃, Ga₂S₃, In₂S₃, SiS, SiS₂, GeS, GeS₂, SnS, SnS₂, PbS, PbS₂, P₂S₅, As₂S₅, Sb₂S₅, Bi₂S₅, and their compounds.

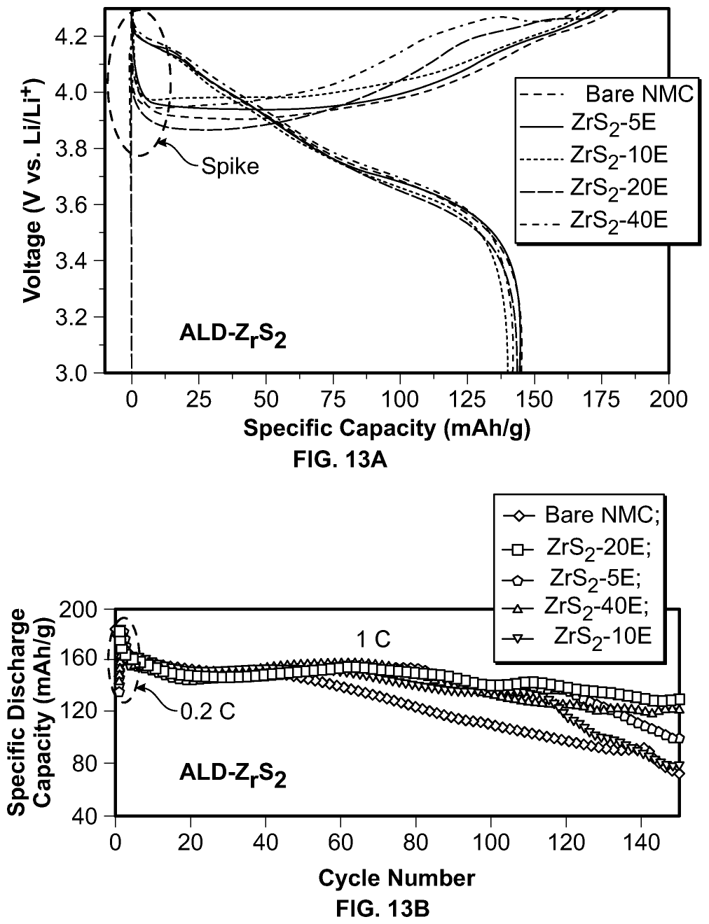

To confirm this, it was further demonstrated that the O₂-reactive ZrS₂ may be used as a coating of NMC811. In other aspects, the embodiments of the present invention concern an ALD process of ZrS₂ . Applying the ZrS₂ coating on NMC811 electrodes via ALD_{E}, it was found that the ZrS₂ coating also enabled improved performance of NMC811 electrodes. FIG. 13A and 13B illustrate the first charge-discharge profiles and long-term cyclability of bare and ZrS₂-coated NMC811 electrodes with different ALD cycles (5, 10, 20, and 40). The ZrS₂-coated NMC811 electrodes were then named as ZrS₂-5E, ZrS₂-10E, ZrS₂-20E, and ZrS₂-40E, respectively. FIG. 13A shows that the spike induced by RLCs could not be removed by ZrS₂ coatings via ALD_{E}. This is consistent to the results in FIGS. 11 and 12. FIG. 13B further reveals that the ZrS₂-20E electrode performed best, while all the ZrS₂-coated NMC811 electrodes also showed some improvement in their performance. All these again strongly support that O₂-reactive sulfides are promising coatings for NMC811.

The feasibility and benefits of these sulfide coatings are not limited to NMC811. They are applicable to any existing cathodes, such as other NMCs (e.g., NMC111, NMC442, NMC532, and NMC622), LFP, LCO, LMO, layered Li-rich Mn-based cathodes with the chemical formular of xLi₂MnO₃·(1−x) LiTMO₂ (TM=Ni, Mn, Co, etc.).

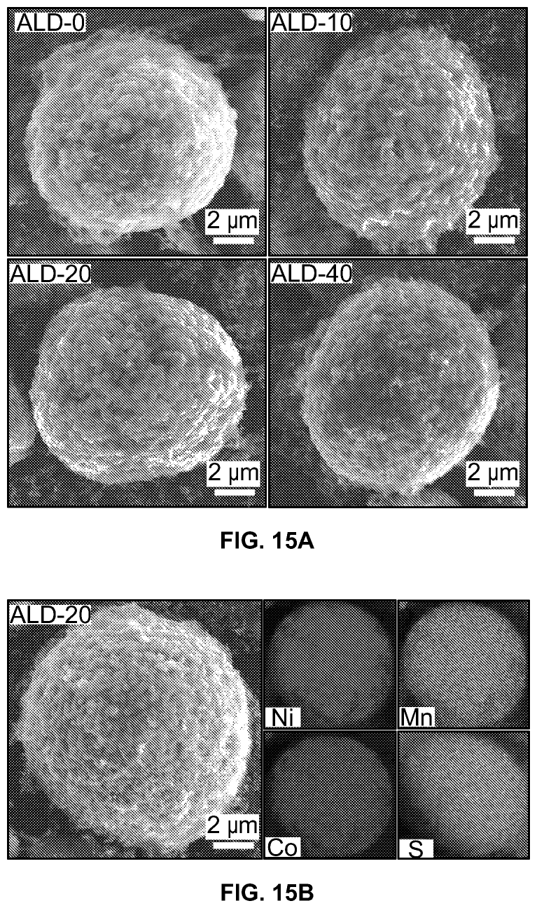

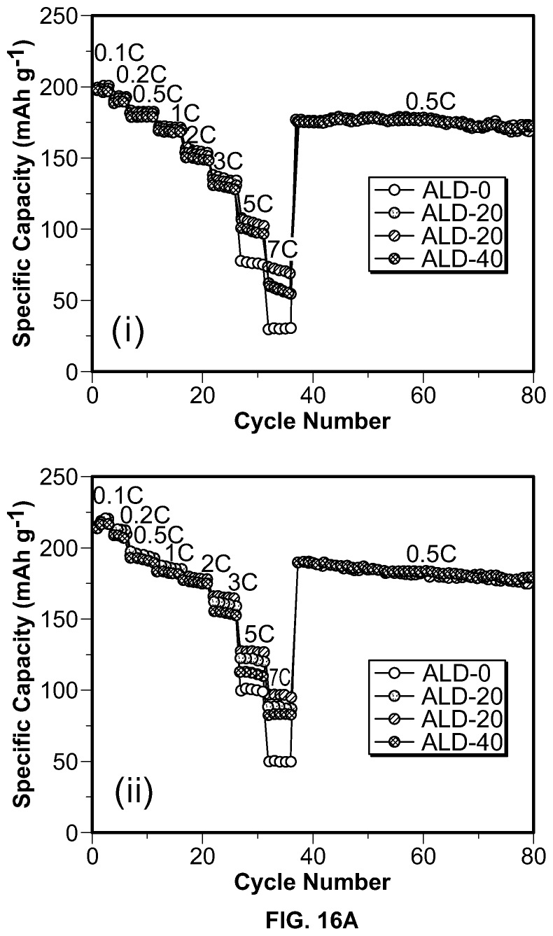

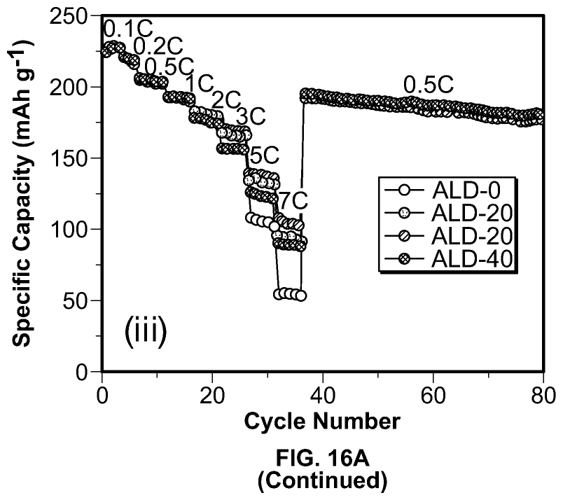

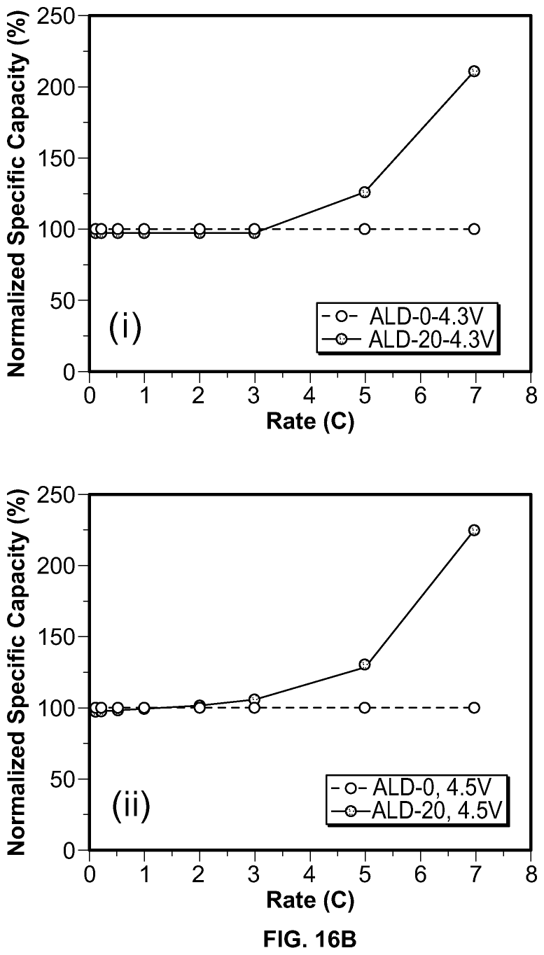

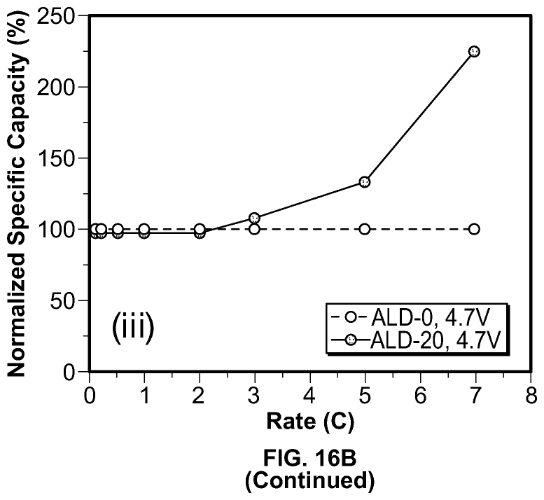

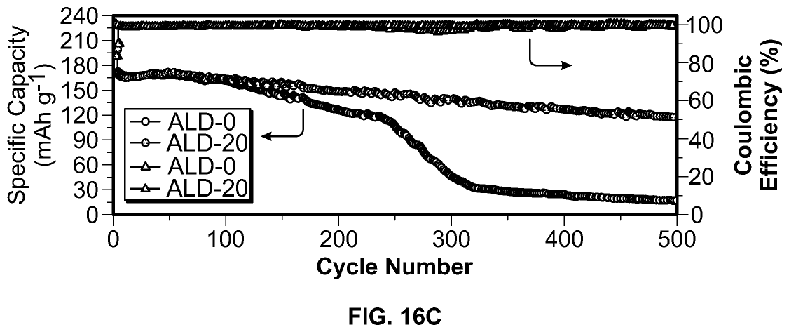

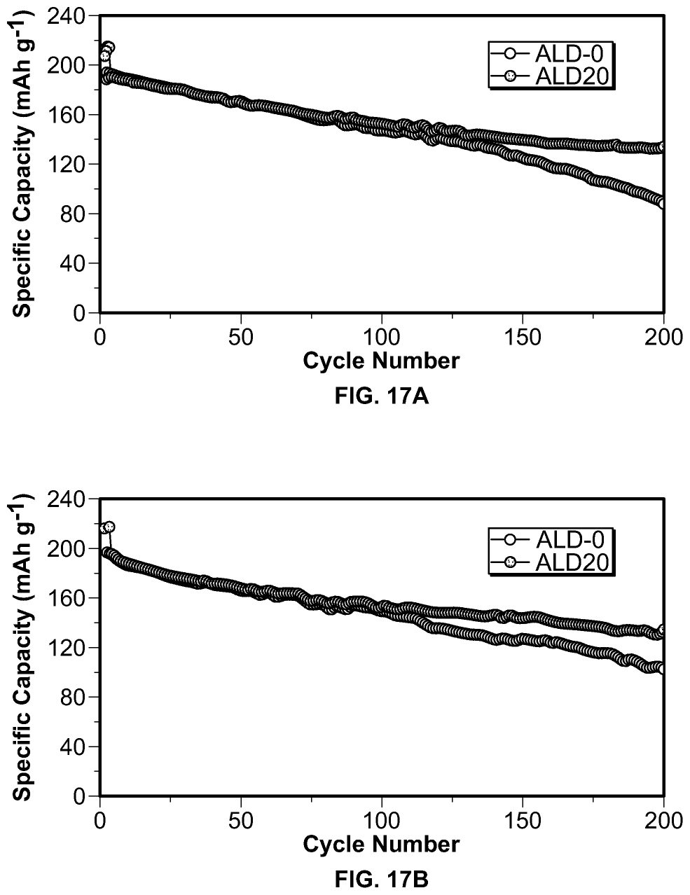

The Li₂S coating was deposited on NMC811 cathodes using atomic layer deposition (ALD). The Li₂S-coated NMC811 cathodes (FIG. 15) exhibited remarkable improvement in capacity retention, rate capability, long-term cyclability (FIG. 16 and FIG. 17), and voltage decline (FIG. 17). The Li₂S coating was verified for beneficial effects in three aspects: (i) improve the mechanical integrity of the NMC811 electrode and NMC powders themselves; (ii) stabilize the interface between the NMC electrode and its electrolyte; and (iii) mitigate the structural phase transition of NMC materials.

The present invention is not limited to Li₂S. It also covers any sulfides that can be used as coating materials to improve the performance of NMC cathodes. Furthermore, this invention is not limited to NMC cathodes. This invention implies that sulfides can be effective to other cathode materials, including LiMn₂O₄ (LMO), olivine LiFePO₄ (LFP), layered LiCoO₂ (LCO), layered LiNi_{0.8}Co_{0.15}Al_{0.05}O₂ (NCA), and layered Li-rich Mn-based cathodes with the chemical formular of xLi₂MnO₃·(1−x) LiTMO₂ (TM=Ni, Mn, Co, etc.).

In other aspects, the present invention comprises NMC811 electrode fabrication, ALD coating of metal sulfides (e.g., Li₂S and ZrS₂), and electrochemical evaluation of NMC811 cathodes.

### Electrode Preparation.

An example of the present invention is an NMC811 electrode laminates containing 86 wt. % NMC811 powder (MSE Supplies), 7 wt. % polyvinylidene fluoride (PVDF, HSV900, MTI Corporation), 7 wt. % carbon black (Timical super C65). To fabricate the laminates, a slurry was first prepared by mixing NMC811 powders, PVDF, and carbon black with a suitable amount of 1-Methyl-2-pyrrolidinone (NMP, 99.5%, Sigma-Aldrich) homogenously. Then, the slurry was coated on Al foils. The resultant NMC laminates were fully dried in air first and then in vacuum at 100° C. for 10 hrs. The mass loading of the prepared NMC811 is ˜7.0 mg cm-2.

Li₂S ALD coatings.

In other aspects of the present invention, an Li₂S coating was deposited on NMC811 laminates at 150° C. using an ALD system (Savannah 200, Cambridge Nanotech Inc., USA) integrated with an Ar-filled glove box. This integrated ALD-glove box facility guaranteed no air-exposure to the Li₂S-coated NMC811 laminates. The Li₂S ALD was proceeded using lithium tertbutoxide (LTB, 98 at. %, Strem Chemicals, Inc.) and hydrogen sulfide (H₂S, 4 at. % in Argon, Airgas) as precursors. Ar was used as the carrier gas of the ALD precursors.

To provide sufficient vapor pressure, the solid LTB was heated to 150° C. in a stainless-steel bubbler. A single ALD cycle was performed with four successive steps: (1) a 3.0 s dose of LTB; (2) a 10.0 s purge using Ar gas to remove excessive LTB and byproducts; (3) a 0.5 s dose of H₂S, and (4) a 10.0 s purge using Ar gas to remove excessive H₂S and byproducts. NMC electrodes were coated with different ALD cycles: 10, 20, and 40 ALD cycles for different coating thicknesses. The growth per cycle of the ALD Li₂S was ˜1.1 Å·cycle⁻¹. Thus, the coating thickness was ˜1, 2, and 4 nm, respectively. To facilitate identifying the different coated electrodes, the resultant ALD-coated electrodes via ALD_{E} were denoted as Li₂S-10E, Li₂S-20E, and Li₂S-40E (or, ALD-10, ALD-20, and ALD-40), respectively. Accordingly, the bare (uncoated) NMC811 electrode was signified as ALD-0.

ZrS₂ALD coatings

In other aspects of the present invention, an ZrS₂ coating was deposited on NMC811 laminates at 150° C. using an ALD system (Savannah 200, Cambridge Nanotech Inc., USA) integrated with an Ar-filled glove box. This integrated ALD-glove box facility guaranteed no air-exposure to the Li₂S-coated NMC811 laminates. The ZrS₂ ALD was proceeded using tetrakis (dimethylamino) zirconium (TDMA-Zr, 98 at. %, Strem Chemicals, Inc.) and hydrogen sulfide (H₂S, 4 at. % in Argon, Airgas) as precursors. Ar was used as the carrier gas of the ALD precursors.

To provide sufficient vapor pressure, the solid LTB was heated to 75° C. in a stainless-steel cylinder. A single ALD cycle was performed with four successive steps: (1) a 0.03 s dose of TDMA-Zr; (2) a 10.0 s purge using Ar gas to remove excessive LTB and byproducts; (3) a 0.5 s dose of H₂S, and (4) a 10.0 s purge using Ar gas to remove excessive H₂S and byproducts. NMC electrodes were coated with different ALD cycles: 5, 10, 20, and 40 ALD cycles for different coating thicknesses. The growth per cycle of the ALD Li₂S was ˜1.0 Å.cycle⁻¹. Thus, the coating thickness was ˜0.5, 1, 2, and 4 nm, respectively. To facilitate identifying the different coated electrodes, the resultant ALD-coated electrodes via ALD_{E} were denoted as ZrS₂-5E, ZrS₂-10E, ZrS₂-20E, and ZrS₂-40E, respectively.

### Materials Characterization.

NMC811 electrodes were observed for morphological characteristics and element distribution, using a scanning electron microscopy (SEM) equipped with an energy dispersive X-ray spectroscopy (EDS). Transmission x-ray microscopy (TXM) was applied to directly observe the tomography of NMC811 particles.

### Electrochemical Measurements.

Coin cells were assembled in the Ar-filled glove box after NMC811 laminates were coated with the ALD Li₂S film. In the glove box, oxygen and water were controlled less than 0.01 ppm. Li metal and Celgard 2325 membrane were used as the anode and the separator, respectively. The electrolyte was composed of 1.2 M LiPF6 in ethylene carbonate (EC)/ethylmethyl carbonate (EMC) (3:7 by weight). All the assembled cells were rested for 10 hours prior to their electrochemical tests at room temperature. Galvanostatic charge-discharge was carried out using an Neware battery test system. The cells were cycled at 0.1 C (1 C=200 mA g⁻) for the initial three cycles and then at 1 C for the rest of cycles via a constant current (CC) mode in the voltage ranges of 3.0-4.3, 3.0-4.5, and 3.0-4.7 V versus Li/Li⁺. Electrochemical impedance spectroscopy (EIS, SP-200 Bio-Logic) measurements were carried out in the frequency range of 10 m Hz to 100 kHz with amplitude voltage of 5 mV by EC Lab software.

While the foregoing written description enables one of ordinary skill to make and use what is considered presently to be the best mode thereof, those of ordinary skill will understand and appreciate the existence of variations, combinations, and equivalents of the specific embodiment, method, and examples herein. The disclosure should therefore not be limited by the above-described embodiments, methods, and examples, but by all embodiments and methods within the scope and spirit of the disclosure.

1. A lithium-ion battery comprising: a cathode having a sulfide coating thereon.

2. The lithium-ion battery of claim 1 wherein said coating Li₂S.

3. The lithium-ion battery of claim 1 wherein said cathode is LiNiₓMn_{y}Co_{z}O₂.

4. The lithium-ion battery of claim 1 wherein said cathode is LiNi_{0.8}Mn_{0.1}Co_{0.1}O₂.

5. The lithium-ion battery of claim 3 wherein said cathode includes one or more of the following materials: LiMn₂O₄ (LMO), olivine LiFePO₄ (LFP), LiCoO₂ (LCO), LiNi_{0.8}Co_{0.15}Al_{0.05}O₂(NCA), and layered Li-rich Mn-based cathodes with the chemical formular of xLi₂MnO₃·(1−x) LiTMO₂ (TM=Ni, Mn, Co, etc.).

6. The lithium-ion battery of claim 1 wherein said coating is from the group comprising:
Na₂S, K₂S, Rb₂S, Cs₂S, Fr₂S, BeS, MgS, SrS, BaS, RaS, Sc₂S₃, Y₂S₃, TiS₂, ZrS₂, HfS₂, V₂S₅, Nb₂S₅, Ta₂S₅, CrS₂, MoS₂, WS₂, MnS, MnS₂, TcS₂, ReS₂, Fe₂S₃, Ru₂S₃, Os₂S₃, CoS, CoS₂, Co₃S₄, Co₉S₈, RhS, RhS₂, NiS, NiS₂, PdS, PdS₂, PtS, PtS₂, CuS, Cu₂S, Ag₂S, AgS, Au₂S, AuS, ZnS, CdS, HgS, B₂S₃, Al₂S₃, Ga₂S₃, In₂S₃, SiS, SiS₂, GeS, GeS₂, SnS, SnS₂, PbS, PbS₂, P₂S₅, As₂S₅, Sb₂S₅, Bi₂S₅, and their compounds.

7. A method of improving a lithium-ion battery comprising the steps of: depositing a sulfide coating on the cathode of said battery.

8. The method of claim 7 wherein said coating is Li₂S.

9. The method of claim 7 wherein said cathode is LiNiₓMn_{y}Co_{z}O₂.

10. The method of claim 7 wherein said cathode is LiNi_{0.8}Mn_{0.1}Co_{0.01}O₂.

11. The method of claim 10 wherein said coating is deposited using atomic layer deposition (ALD).

12. The method of claim 10 wherein said coating is deposited using ALD_{E}.

13. The method of claim 10 wherein said coating is deposited using ALD_{P}.

14. The method of claim 10 wherein said coating is deposited using ALD_{P}-T.

15. The method of claim 10 wherein said coating provides an antioxidative surface.

16. The method of claim 15 wherein said antioxidative surface inhibits microcracking, oxygen release, transition metal dissolution, irreversible phase transition, and electrolyte decomposition.

17. The method of claim 7 wherein said coating is from the group comprising: Na₂S, K₂S, Rb₂S, Cs₂S, Fr₂S, BeS, MgS, SrS, BaS, RaS, Sc₂S₃, Y₂S₃, TiS₂, ZrS₂, HfS₂, V₂S₅, Nb₂S₅, Ta₂S₅, CrS₂, MoS₂, WS₂, MnS, MnS₂, TcS₂, ReS₂, Fe₂S₃, Ru₂S₃, Os₂S₃, CoS, CoS₂, Co₃S₄, Co₉S₈, RhS, RhS₂, NiS, NiS₂, PdS, PdS₂, PtS, PtS₂, CuS, Cu₂S, Ag₂S, AgS, Au₂S, AuS, ZnS, CdS, HgS, B₂S₃, Al₂S₃, Ga₂S₃, In₂S₃, SiS, SiS₂, GeS, GeS₂, SnS, SnS₂, PbS, PbS₂, P₂S₅, As₂S₅, Sb₂S₅, Bi₂S₅, and their compounds.

18. The method of claim 7 wherein said cathode includes one or more of the following materials: LiMn₂O₄ (LMO), olivine LiFePO₄ (LFP), LiCoO₂ (LCO), LiNi_{0.8}Co_{0.15}Al_{0.05}O₂ (NCA), and layered Li-rich Mn-based cathodes with the chemical formular of xLi₂MnO₃·(1−x) LiTMO₂ (TM=Ni, Mn, Co, etc.).
